(19) United States
(12) Patent Application Publication
(10) Pub. No.: US 2025/0059638 A1
(43) Pub. Date: Feb. 20, 2025

(54) MASK ASSEMBLY, AND APPARATUS FOR MANUFACTURING DISPLAY APPARATUS

(71) Applicant: Samsung Display Co., Ltd., Yongin-si (KR)

(72) Inventors: Sangwoo Jo, Yongin-si (KR); Youngeun Ryu, Yongin-si (KR); Junghyun Ahn, Yongin-si (KR); Yuri Lee, Yongin-si (KR); Sangheon Jeon, Yongin-si (KR)

(73) Assignee: Samsung Display Co., Ltd., Yongin-si (KR)

(21) Appl. No.: 18/754,712

(22) Filed: Jun. 26, 2024

(30) Foreign Application Priority Data
Aug. 16, 2023 (KR) 10-2023-0107225

(51) Int. Cl. C23C 14/04

(52) U.S. Cl. CPC C23C 14/042

(57) ABSTRACT

A mask assembly and an apparatus for manufacturing a display apparatus are provided. The mask assembly includes a mask frame including an opening area, at least one mask sheet covering the opening area of the mask frame, and a support stick disposed between the mask frame and the at least one mask sheet, extending in a first direction to traverse the opening area, and having both ends fixed to the mask frame. The at least one mask sheet includes submasks disposed side by side in a direction intersecting the first direction in which the support stick extends, and a connection stick disposed between the submasks and connecting two adjacent submasks among the submasks. The connection stick overlaps the support stick in a plan view.

### CROSS-REFERENCE TO RELATED APPLICATION(S)

This application claims priority to and benefits of Korean Patent Application No. 10-2023-0107225 under 35 U.S.C. § 119, filed on Aug. 16, 2023, in the Korean Intellectual Property Office, the entire contents of which are incorporated herein by reference.

### BACKGROUND

### 1. Technical Field

One or more embodiments relate to a mask assembly, and a method of manufacturing a display apparatus, and, to a mask assembly capable of improving deposition quality of a display apparatus by preventing a shadow phenomenon, and an apparatus for manufacturing a display apparatus.

### 2. Description of the Related Art

Recently, electronic devices have come into widespread use. Electronic devices are used in a variety of ways, such as mobile electronic devices and fixed electronic devices. In order to support various functions, such electronic devices include a display capable of providing a user with visual information such as images or videos.

A display is a device that visually displays data, and is formed by depositing various layers such as organic layers and metal layers. Deposition materials may be deposited to form multiple layers of the display. In other words, a deposition material is sprayed from a deposition source, and is deposited on a substrate through a mask assembly.

In this case, a mask sheet may be an extended mask sheet in which a plurality of submasks are connected to manufacture a display having a wide width. The plurality of submasks are connected to one another by connection sticks. In this case, there is a need to prevent interference with a support stick that supports the mask sheet.

Information disclosed in this background may contain information that does not form the prior art that may already be known in this country to a person of ordinary skill in the art.

### SUMMARY

One or more embodiments include a mask assembly capable of improving the deposition quality of a display apparatus by preventing a shadow phenomenon, and an apparatus for manufacturing a display apparatus.

However, the one or more embodiments are only examples, and the scope of the disclosure is not limited thereto.

Additional aspects will be set forth in part in the description which follows and, in part, will be apparent from the description, or may be learned by practice of the presented embodiments of the disclosure

According to one or more embodiments, a mask assembly may include a mask frame comprising an opening area; at least one mask sheet covering the opening area of the mask frame; and a support stick disposed between the mask frame and the at least one mask sheet, the support stick extending in a first direction to traverse the opening area, the support stick having ends fixed to the mask frame. The at least one mask sheet may include a plurality of submasks disposed side by side in a direction intersecting the first direction in which the support stick extends, and a connection stick disposed between the plurality of submasks and connecting two adjacent submasks among the plurality of submasks. The connection stick overlaps the support stick in a plan view.

The support stick may include an opening formed in the first direction, and the connection stick may be accommodated in the opening.

A width of the opening may be formed to be larger than a width of the connection stick by at least about 12 μm but less than about 18 μm.

A thickness of the connection stick and a thickness of the support stick may be same.

The plurality of submasks may contact the support stick.

The plurality of submasks may include a first submask, a second submask, and a third submask disposed side by side in a second direction, and the support stick may include a first support stick extending in the first direction between the first submask and the second submask in a plan view, the first support stick including a first opening accommodating a first connection stick between the first submask and the second submask, and a second support stick extending in the first direction between the second submask and the third submask in a plan view, the second support stick including a second opening accommodating a second connection stick between the second submask and the third submask.

A width of the first support stick and a width of the second support stick may be different from each other.

A width of the first opening and a width of the second opening may be different from each other.

The at least one mask sheet may include a first mask sheet and a second mask sheet disposed side by side in the first direction, the support stick may include a first opening and a second opening spaced apart from each other in the first direction, a connection stick of the first mask sheet may be accommodated in the first opening, and a connection stick of the second mask sheet may be accommodated in the second opening.

The support stick may include a pair of parallel substicks each extending in the first direction, and the connection stick may be accommodated between the pair of parallel substicks.

A distance between the pair of parallel substicks may be formed to be larger than a width of the connection stick by at least about 12 μm but less than about 18 μm.

The plurality of submasks may include a first submask, a second submask, and a third submask disposed side by side in a second direction, and the support stick may include a first support stick extending in the first direction between the first submask and the second submask in a plan view, the first support stick including a pair of parallel first substicks to accommodate a first connection stick between the first submask and the second submask, and a second support stick extending in the first direction between the second submask and the third submask in a plan view, the second support stick including a pair of parallel second substicks to accommodate a second connection stick between the second submask and the third submask.

A separation distance between the pair of parallel first substicks may be different from a separation distance between the pair of parallel second substicks.

According to one or more embodiments, an apparatus for manufacturing a display apparatus may include a mask assembly facing a display substrate; and a deposition source facing the mask assembly on a side opposite to a side on which the display substrate is disposed. The mask assembly may include a mask frame comprising an opening area; at least one mask sheet covering the opening area of the mask frame; and a support stick disposed between the mask frame and the at least one mask sheet, extending in a first direction to traverse the opening area, the support stick having ends fixed to the mask frame. The at least one mask sheet may include a plurality of submasks disposed side by side in a direction intersecting the first direction in which the support stick extends, and a connection stick disposed between the plurality of submasks and connecting two adjacent submasks among the plurality of submasks. The connection stick overlaps the support stick in a plan view.

The support stick may include an opening formed in the first direction, and the connection stick may be accommodated in the opening of the support stick.

A width of the opening may be formed to be larger than a width of the connection stick by at least about 12 μm but less than about 18 μm.

The plurality of submasks may include a first submask, a second submask, and a third submask disposed side by side in a second direction, and the support stick may include a first support stick extending in the first direction between the first submask and the second submask in a plan view, the first support stick including a first opening accommodating a first connection stick between the first submask and the second submask, and a second support stick extending in the first direction between the second submask and the third submask in a plan view, the second support stick including a second opening accommodating a second connection stick between the second submask and the third submask.

A width of the first support stick and a width of the second support stick may be different.

A width of the first opening and a width of the second opening may be different.

The support stick may include a pair of parallel substicks each extending in the first direction, and the connection stick may be accommodated between the pair of parallel substicks.

These and/or other aspects will become apparent and more readily appreciated from the following description of the embodiments, the claims, and the accompanying drawings.

### BRIEF DESCRIPTION OF THE DRAWINGS

The above and other aspects, features, and advantages of embodiments will be more apparent from the following description taken in conjunction with the accompanying drawings, in which:

FIG. 1 is a schematic cross-sectional view illustrating an apparatus for manufacturing a display apparatus, according to an embodiment;

FIG. 2 is a schematic perspective view of a mask assembly according to an embodiment;

FIG. 3 is a schematic plan view of a mask sheet according to an embodiment;

FIG. 4 is a schematic cross-sectional view of a mask sheet according to an embodiment, and corresponds to a cross-section taken along line IV-IV′ of FIG. 3;

FIG. 5 is a schematic plan view of a support stick according to an embodiment;

FIG. 6 is a schematic cross-sectional view of a mask assembly according to an embodiment, and corresponds to a cross-section taken along line VI-VI′ of FIG. 5;

FIG. 7 is a schematic cross-sectional view illustrating a comparison between a mask assembly according to an embodiment and a mask assembly according to a comparative example.

FIG. 8 is a schematic plan view of a support stick according to an embodiment;

FIGS. 9 and 10 are schematic plan views of support sticks according to other embodiments;

FIG. 11 is a schematic plan view of a display apparatus manufactured using a display apparatus manufacturing apparatus, according to an embodiment; and

FIG. 12 is a schematic cross-sectional view of the display apparatus manufactured using a display apparatus manufacturing apparatus, according to an embodiment, and corresponds to a cross-section of the display apparatus taken along line XII-XII′ of FIG. 11.

### DETAILED DESCRIPTION OF THE EMBODIMENTS

Reference will now be made in detail to embodiments, examples of which are illustrated in the accompanying drawings, wherein like reference numerals refer to like elements throughout. In this regard, embodiments may have different forms and should not be construed as being limited to the descriptions set forth herein. Accordingly, the embodiments are described below, by referring to the figures, to explain aspects of the description.

As used herein, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Throughout the disclosure, the expression “at least one of a, b or c” indicates only a, only b, only c, both a and b, both a and c, both b and c, all of a, b, and c, or variations thereof.

As the disclosure allows for various changes and numerous embodiments, embodiments will be illustrated in the drawings and described in detail in the written description. Hereinafter, effects and features of the disclosure and a method for accomplishing them will be described more fully with reference to the accompanying drawings, in which embodiments of the disclosure are shown. The disclosure may, however, be embodied in many different forms and should not be construed as limited to the embodiments set forth herein.

One or more embodiments will be described below in more detail with reference to the accompanying drawings. Those components that are the same as or are in correspondence with each other are rendered the same reference numeral regardless of the figure number, and redundant explanations may be omitted.

It will be understood that although the terms “first,” “second,” etc. may be used herein to describe various components, these components should not be limited by these terms. These components are only used to distinguish one component from another. For example, a first element may be referred to as a second element, and similarly, a second element may be referred to as a first element without departing from the scope of the disclosure.

As used herein, the singular forms “a,” “an,” and “the” are intended to include the plural forms as well, unless the context clearly indicates otherwise.

It will be further understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be understood that when a layer, region, or component is referred to as being “formed on” another layer, region, or component, it can be directly or indirectly formed on the other layer, region, or component. For example, intervening layers, regions, or components may be present.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

Sizes of elements in the drawings may be exaggerated or reduced for convenience of explanation. For example, since sizes and thicknesses of components in the drawings are arbitrarily illustrated for convenience of explanation, embodiments are not limited thereto.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

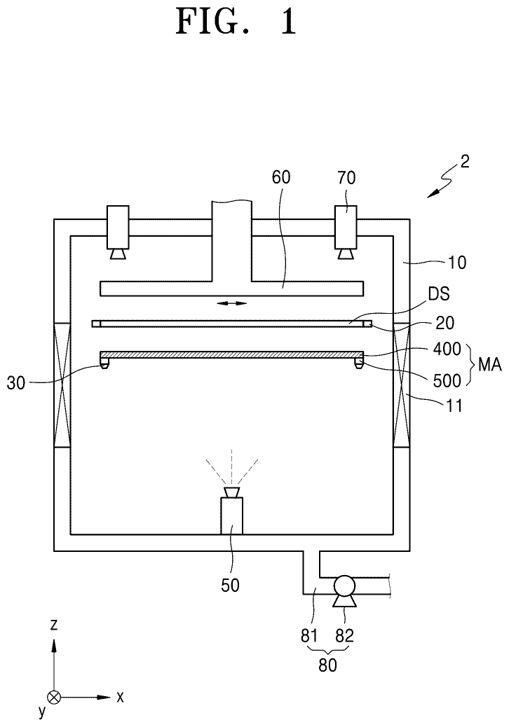

FIG. 1 is a schematic cross-sectional view illustrating an apparatus 2 for manufacturing a display apparatus, according to an embodiment.

The apparatus 2 may include a chamber 10, a first support 20, a second support 30, a mask assembly MA, a deposition source 50, a magnetic force unit 60, a vision unit 70, and a pressure adjuster 80.

The chamber 10 may have a space formed therein, and a display substrate DS and the mask assembly MA may be accommodated in the chamber 10. An open portion may be formed in the chamber 10, and a gate valve 11 may be provided in the open portion of the chamber 10. In this case, according to an operation of the gate valve 11, the open portion of the chamber 10 may be opened or closed.

The display substrate DS may refer to a substrate 100 during manufacturing of a display apparatus, on which at least one layer from among an organic layer, an inorganic layer, and a metal layer is deposited on the substrate 100, which will be described later. By way of example, the display substrate DS may be a substrate 100 on which any of the organic layer, the inorganic layer, and the metal layer has not yet been deposited.

The first support 20 may support the display substrate DS. The first support 20 may be in the form of a plate fixed to the inside of the chamber 10. According to an embodiment, the first support 20 may be in the shape of a shuttle having the display substrate DS safely seated thereon and linearly movable within the chamber 10. According to an embodiment, the first support 20 may include an electrostatic chuck or adhesive chuck disposed in the chamber 10 so as to be fixed to the chamber 10 or be movable within the chamber 10.

The second support 30 may support the mask assembly MA. In this case, the second support 30 may be arranged (or disposed) within the chamber 10. The second support 30 may be able to finely adjust a location of the mask assembly MA. In this case, the second support 30 may be provided with a separate driver or alignment unit to enable the mask assembly MA to move in different directions.

According to an embodiment, the second support 30 may be in the shape of a shuttle. In this case, the second support 30 may have the mask assembly MA safely seated thereon, and may transport the mask assembly MA. For example, the second support 30 may move outside the chamber 10, have the mask assembly MA safely seated thereon, and enter the inside of the chamber 10 from the outside of the chamber 10.

In the above case, the first support 20 and the second support 30 may be formed integrally with each other. In this case, the first support 20 and the second support 30 may include a movable shuttle. The first support 20 and the second support 30 may include a structure for fixing the mask assembly MA and the display substrate DS while the display substrate DS is being seated on the mask assembly MA, and may linearly move the display substrate DS and the mask assembly MA at the same time.

However, for convenience of explanation, a case where the first support 20 and the second support 30 are formed to be separate from each other and are disposed at different positions, and the first support 20 and the second support 30 are disposed inside the chamber 10 will now be described in detail.

The deposition source 50 may be disposed to face the mask assembly MA. A deposition material may be accommodated in the deposition source 50, and may be heated to be evaporated or sublimated. The deposition source 50 may be fixedly placed inside the chamber 10 or may be placed inside the chamber 10 to linearly move in one direction.

The mask assembly MA may be arranged within the chamber 10. The mask assembly MA may include a mask frame 500 and a mask sheet 400. This will be described below in more detail. The deposition material may pass through the mask assembly MA and may be deposited on the display substrate DS.

The magnetic force unit 60 may be disposed inside the chamber 10 to face the display substrate DS and/or the mask assembly MA. The magnetic force unit 60 may apply A magnetic force to the mask assembly MA to force the mask assembly MA toward the display substrate DS. For example, the magnetic force unit 60 may not only prevent the mask sheet 400 from sagging but also may allow the mask sheet 400 to be adjacent to the display substrate DS. The magnetic force unit 60 may maintain a uniform gap between the mask sheet 400 and the display substrate DS.

The vision unit 70 may be arranged within the chamber 10 and may photograph respective locations of the display substrate DS and the mask sheet 400. In this case, the vision unit 70 may include a camera that photographs the display substrate DS and the mask assembly MA. Based on an image captured by the vision unit 70, the respective locations of the display substrate DS and the mask assembly MA may be as selected, and deformation of the mask assembly MA may be confirmed. Based on the image, the location of the display substrate DS on the first support 20 may be finely adjusted, or the location of the mask assembly MA on the second support 30 may be finely adjusted. However, a case of aligning the respective locations of the display substrate DS and the mask assembly MA by finely adjusting the location of the mask assembly MA on the second support 30 will now be focused on and described in detail.

The pressure adjuster 80 may be connected to the chamber 10 and may adjust an internal pressure of the chamber 10. For example, the pressure adjuster 80 may adjust the internal pressure of the chamber 10 to be the same as or similar to atmospheric pressure. The pressure adjuster 80 may also adjust the internal pressure of the chamber 10 to be the same as or similar to a vacuum state.

The pressure adjuster 80 may include a connection pipe 81 connected to the chamber 10, and a pump 82 provided on the connection pipe 81. In this case, depending on an operation of the pump 82, outside air may be introduced through the connection pipe 81 or the gas inside the chamber 10 may be guided to the outside through the connection pipe 81.

Regarding a method of manufacturing a display apparatus (not shown) by using the apparatus 2 for manufacturing a display apparatus as described above, first, the display substrate DS may be prepared.

The pressure adjuster 80 may maintain the inside of the chamber 10 at a state equal to or similar to atmospheric pressure, and the gate valve 11 may operate to open the open portion of the chamber 10.

Thereafter, the display substrate DS may be inserted from the outside of the chamber 10 to the inside of the chamber 10. At this time, the display substrate DS may be inserted into the chamber 10 in various ways. For example, the display substrate DS may be inserted from the outside of the chamber 10 into the inside of the chamber 10 through a robot arm or the like disposed outside the chamber 10. According to an embodiment, in case that the first support 20 is formed in a shuttle shape, the first support 20 may be carried out from the inside of the chamber 10 to the outside of the chamber 10, and the display substrate DS may be seated on the first support 20 through an separate robot or the like placed outside the chamber 10, and the first support 20 may be inserted from the outside of the chamber 10 into the inside of the chamber 10.

The mask assembly MA may be in a state of being arranged within the chamber 10 as described above. According to an embodiment, the mask assembly MA may be inserted from the outside of the chamber 10 into the chamber 10 in the same or similar manner as or to the display substrate DS.

In case that the display substrate DS is inserted into the chamber 10, the display substrate DS may be seated on the first support 20. At this time, the vision unit 70 may photograph the respective locations of the display substrate DS and the mask assembly MA. Based on an image captured by the vision unit 70, the respective locations of the display substrate DS and the mask sheet 400 may be as selected. At this time, the apparatus 2 for manufacturing a display apparatus may include a separate controller (not shown) to as selectable the respective locations of the display substrate DS and the mask assembly MA.

In case that the as selectable of the respective locations of the display substrate DS and the mask assembly MA is completed, the second support 30 may finely adjust the location of the mask assembly MA.

Thereafter, the deposition source 50 may operate to supply the deposition material to the mask assembly MA, and the deposition material that has passed through a plurality of pattern holes of the mask sheet 400 may be deposited on the display substrate DS. At this time, the deposition source 50 may move parallel to the display substrate DS and the mask assembly MA, or the display substrate DS and the mask assembly MA may move parallel to the deposition source 50. In other words, the deposition source 50 may move relative to the display substrate DS and the mask assembly MA. At this time, the pump 82 may maintain the internal pressure of the chamber 10 in a form similar to or the same as a vacuum by sucking the gas inside the chamber 10 and discharging the gas to the outside.

As described above, the deposition material supplied by the deposition source 50 may pass through the mask assembly MA and may be deposited on the display substrate DS, thereby forming at least one of a plurality of layers, such as an organic layer, an inorganic layer, and a metal layer, stacked in a display apparatus to be described later.

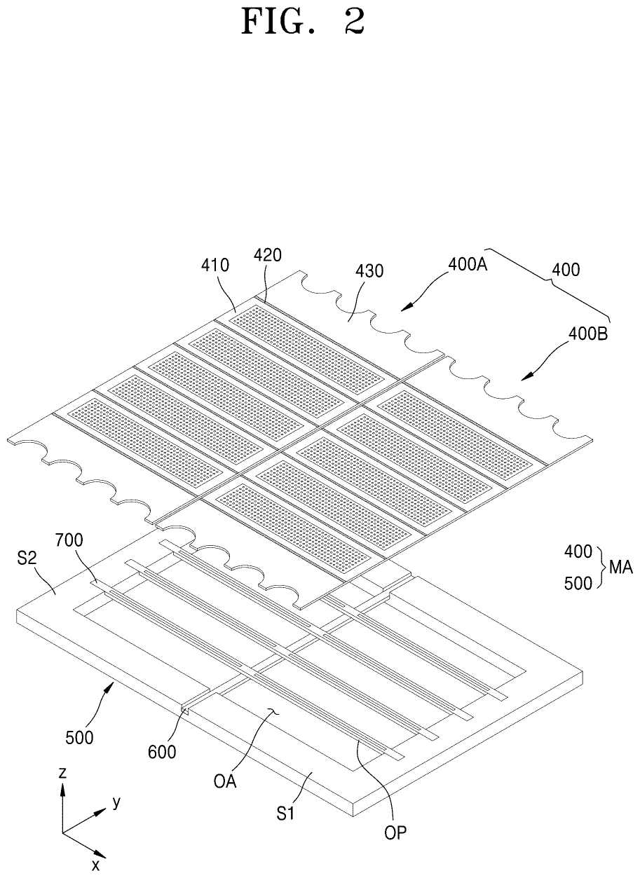

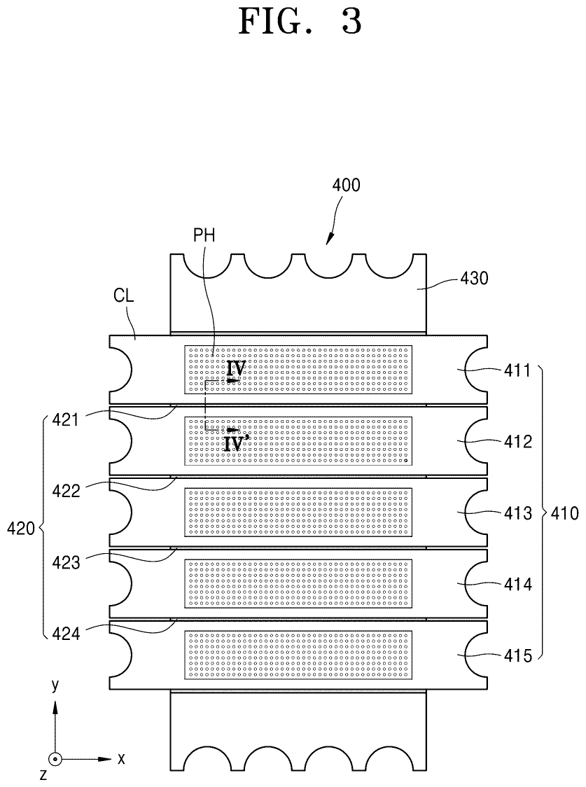

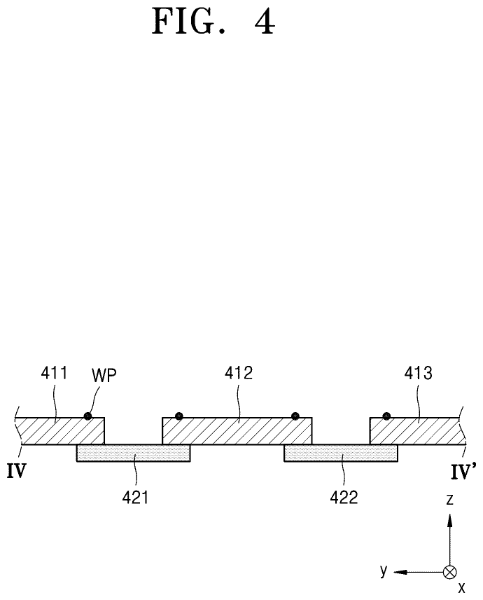

FIG. 2 is a schematic perspective view of the mask assembly MA according to an embodiment, and illustrates the mask assembly usable in the above-described apparatus for manufacturing a display apparatus. FIG. 3 is a schematic plan view of the mask sheet 400 according to an embodiment. FIG. 4 is a schematic cross-sectional view of the mask sheet 400 according to an embodiment, and may correspond to a cross-section taken along line IV-IV′ of FIG. 3.

Referring to FIGS. 2 through 4, the mask assembly MA may include the mask frame 500, the mask sheet 400, a shielding stick 600, and a support stick 700.

The mask frame 500 may be formed by connecting a plurality of sides to one another, and may include an opening area OA defined by the plurality of sides. In other words, the opening area OA may be formed by being surrounded by the plurality of sides, and the opening area OA may pass through the center of the mask frame 500.

According to an embodiment, the mask frame 500 may be a rectangular frame. Of course, the shape of the mask frame 500 is not limited thereto, and may be various polygonal shapes. For convenience of description, a case where the mask frame 500 is a rectangular frame will now be described in detail. It is to be understood that the shapes disclosed herein include shapes substantial to the shapes disclosed herein.

In case that the mask frame 500 is a rectangular frame, the plurality of sides may include a first side S1 extending in a first direction (for example, an x direction in FIG. 2) and a second side S2 extending in a second direction (for example, a y direction of FIG. 2) intersecting the first direction. The first side S1 may be provided in a pair to face each other, and the second side S2 may be provided in a pair to face each other, and thus the first sides S1 and the second sides S2 may be connected to each other. According to an embodiment, the first side S1 may be a long side, and the second side S2 may be a short side. However, embodiments are not limited thereto. The first side S1 may be a short side and the second side S2 may be a long side, or the first side S1 and the second side S2 may have the same lengths. For convenience of description, a case where the first side S1 is a long side and the second side S2 is a short side will now be focused on and described.

The mask sheet 400 may be installed by being stretched on the mask frame 500. The opening area OA at the center of the mask frame 500 may be covered by the mask sheet 400. In FIG. 2, the mask sheet 400 may include a first mask sheet 400A and a second mask sheet 400B. However, according to an embodiment, one or more mask sheets 400 may be provided. In case that two or more mask sheets 400 are provided, the mask sheets 400 may be arranged on the mask frame 500 so that they are side by side. For example, the mask sheets 400 may be arranged side by side in the first direction (x direction in FIG. 2). Both ends of the mask sheet 400 may be fixed to the mask frame 500 by, for example, welding.

According to an embodiment, the mask sheet 400 may be an extended mask sheet 400 in which a plurality of submasks 410 are connected to one another. The mask sheet 400 has a very large width (length in the x direction of FIG. 3), so that a display apparatus with a very large width may be manufactured.

According to an embodiment, the mask sheet 400 may include a submask 410, a connection stick 420, and a main clamping unit 430. According to an embodiment, the submask 410 may be a mask extending in the first direction (x direction in FIG. 3). However, embodiments are not limited thereto. The submask 410 may be provided in plurality. For example, the submask 410 may include a first submask 411, a second submask 412, a third submask 413, a fourth submask 414, and a fifth submask 415. As shown in FIG. 3, the number of submasks 410 may be 5. However, embodiments are not limited thereto, and there may be five or fewer submasks, or five or more submasks. For convenience of description, the first submask 411, the second submask 412, and the third submask 413 will now be focused on and described.

Each submask 410 may include one or more pattern holes PH. The pattern hole PH may be a through hole formed to allow the deposition material to pass through the submask 410. The deposition material that has passed through the submask 410 may be deposited on the display substrate DS.

The first submask 411, the second submask 412, and the third submask 413 may be arranged side by side in the second direction (y direction in FIG. 3) intersecting the first direction. The first submask 411, the second submask 412, and the third submask 413 may be spaced a selectable distance apart from one another in the second direction.

A plurality of submasks 410, for example, the first submask 411, the second submask 412, and the third submask 413, may be connected to one another by the connection stick 420. In detail, the first submask 411 and the second submask 412 spaced apart from each other in the second direction may be connected to each other by a first connection stick 421. As shown in FIG. 4, the first connection stick 421 may be arranged such that a portion of the first connection stick 421 overlaps the first submask 411 and the second submask 412. In this case, the first connection stick 421 may be disposed on a lower surface of the first submask 411 (for example, a −z direction surface in FIG. 4) and a lower surface of the second submask 412. According to an embodiment, the first connection stick 421 may be spot welded to welding points WP located (or disposed) on respective upper surfaces of the first submask 411 and the second submask 412, and thus may be fixed to the first submask 411 and the second submask 412.

Similarly, the second submask 412 and the third submask 413 spaced apart from each other in the second direction may be connected to each other by a second connection stick 422. As shown in FIG. 4, the second connection stick 422 may be arranged such that a portion of the second connection stick 422 overlaps the second submask 412 and the third submask 413. In this case, the second connection stick 422 may be disposed on the lower surface of the second submask 412 and a lower surface of the third submask 413. According to an embodiment, the second connection stick 422 may be spot welded to welding points WP located on respective upper surfaces of the second submask 412 and the third submask 413, and thus may be fixed to the second submask 412 and the third submask 413.

The connection stick 420 may extend in the direction in which the submask 410 extends, for example, in the first direction. The connection stick 420 may connect the plurality of submasks 410 to one another while simultaneously shielding spaces between the plurality of submasks 410.

According to an embodiment, the connection stick 420 may be disposed on a lower layer of the submask 410. In other words, because the connection stick 420 is welded and connected to the lower surface of the submask 410, the connection stick 420 may be disposed as the lower layer of the submask 410 while forming a step.

Clamping units CL respectively disposed on both ends of each submask 410 in a lengthwise direction (for example, the x direction in FIG. 3) may be used to clamp and extend each submask 410 in case that connecting the submasks 410 to each other. The clamping portion CL of each submask 410 may be cut after connecting the submasks 410 to each other as shown in FIG. 2.

The main clamping unit 430 may be connected to submasks 410 disposed one both ends or an end in the second direction from among the plurality of submasks 410 disposed side by side in the second direction. For example, as shown in FIG. 3, the main clamping unit 430 may be connected to the first submask 411 and the fifth submask 415. Similar to the above description, the main clamping unit 430 may be connected to the submask 410 by the connection stick 420, The main clamping unit 430 may be used to clamp the mask sheet 400 and stretch the mask sheet 400 in the second direction in case that welding and fixing the mask sheet 400 to the mask frame 500. According to an embodiment, the main clamping unit 430 may be cut after the mask sheet 400 is fixed to the mask frame 500.

Referring back to FIG. 2, the shielding stick 600 may be disposed between the mask frame 500 and the mask sheet 400 and may shield a space between the plurality of mask sheets 400. According to an embodiment, the shielding stick 600 may be provided as one shielding stick and may shield a space between the first mask sheet 400A and the second mask sheet 400B. According to an embodiment, in case that three or more mask sheets 400 are provided, a plurality of shielding sticks 600 may be provided, and the plurality of shielding sticks 600 may be spaced apart from one another in the first direction and arranged in parallel to one another. The shielding stick 600 may extend in the second direction (for example, the y direction in FIG. 2) to traverse the inside of the mask frame 500, for example, the opening area OA thereof. The mask frame 500 may include a hole for accommodating both ends of the shielding stick 600. The shielding stick 600 may be located between the plurality of mask sheets 400 and thus may shield the deposition material from passing between two adjacent mask sheets 400.

The support stick 700 may extend in the first direction (for example, the x direction in FIG. 2) to traverse the inside of the mask frame 500, for example, the opening area OA thereof. According to an embodiment, a plurality of support sticks 700 may be provided, and the plurality of support sticks 700 may be spaced apart from one another in the second direction (for example, the y direction in FIG. 2) and arranged in parallel to one another. The support sticks 700 may intersect the shielding stick 600 in the opening area OA and may be located above the shielding stick 600. The mask frame 500 may include a hole for accommodating both ends of the shielding stick 700, but embodiments are not limited thereto. The support stick 700 may support the mask sheet 400 in the opening area OA to prevent the mask sheet 400 from sagging.

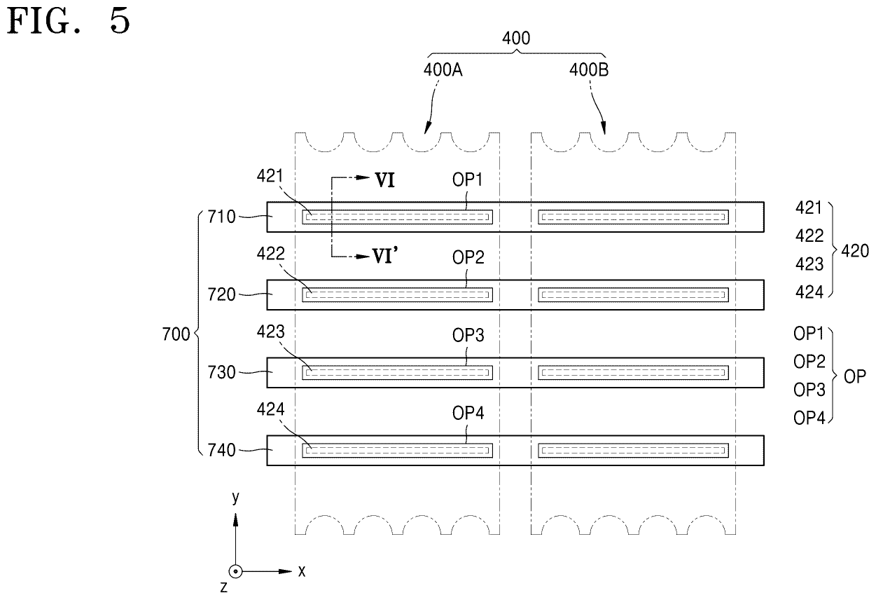

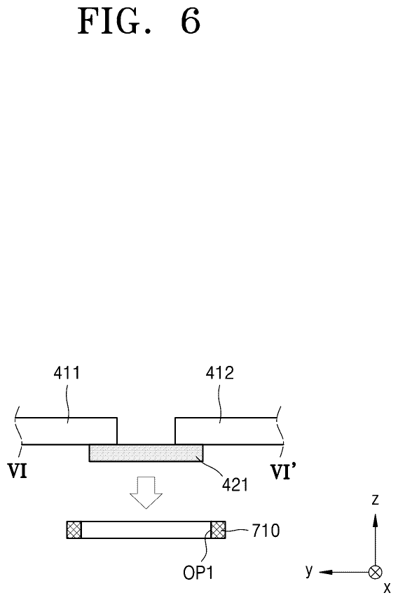

FIG. 5 is a schematic plan view of the support stick 700 according to an embodiment. FIG. 6 is a schematic cross-sectional view of a mask assembly according to an embodiment, and may correspond to a cross-section taken along line VI-VI′ of FIG. 5.

Referring to FIGS. 5 and 6, according to an embodiment, the support stick 700 may be arranged to overlap the connection stick 420 of the mask sheet 400 in a plan view. In detail, the support stick 700 may include a first support stick 710, a second support stick 720, a third support stick 730, and a fourth support stick 740. The first support stick 710 may extend across the mask sheet 400. For example, the first support stick 710 may extend in the first direction between the first submask 411 and the second submask 412. At this time, the first support stick 710 may be arranged to overlap the first connection stick 421 of the mask sheet 400. Similarly, it will be understood that the second through fourth support sticks 720 through 740 may be arranged to overlap the second through fourth connection sticks 422 through 424 of the mask sheet 400. Because each of the second through fourth support sticks 720 through 740 is similar to the first support stick 710, the following description will focus on the first support stick 710.

According to an embodiment, each support stick 700 may include an opening OP. The opening OP may be a through hole extending in the direction in which the support stick 700 extends, for example, in the first direction. According to an embodiment, the openings OP may be provided in a number corresponding to the number of mask sheets 400. For example, in case that two mask sheets 400 are provided as shown in FIG. 2, each support stick 700 may include two openings OP to correspond to the first mask sheet 400A and the second mask sheet 400B.

The opening OP may accommodate the connection stick 420 described above. In other words, a width of the connection stick 420 (for example, a length in the y direction in FIG. 5) may be formed to be greater than that of the opening OP so that the connection stick 420 may be accommodated in the opening OP. Accordingly, as shown in FIG. 6, the connection stick 420 may be accommodated in the opening OP formed in the support stick 700, and the submask 410 may be supported in contact with the support stick 700. In this case, the connection stick 420 is not disposed on the support stick 700 but is accommodated inside the support stick 700, and thus a step difference between the support stick 700 and the submask 410 may be prevented.

According to an embodiment, the width of the opening OP may be formed to be greater than that of the connection stick 420 by at least about 12 μm but less than about 18 μm. Accordingly, a tolerance for accommodating the connection stick 420 may be secured, and at the same time a cleaning solution may be readily discharged without accumulating between the support stick 700 and the connection stick 420 during cleaning of the mask assembly MA.

According to an embodiment, a thickness (length in the z direction) of the connection stick 420 may be equal to a thickness (length in the z direction) of the support stick 700. Therefore, in case that the mask sheet 400 is supported by the support stick 700, the submasks 410 may be supported in contact with the support stick 700, and a step difference between the connection stick 420 and the support stick 700 may not be formed.

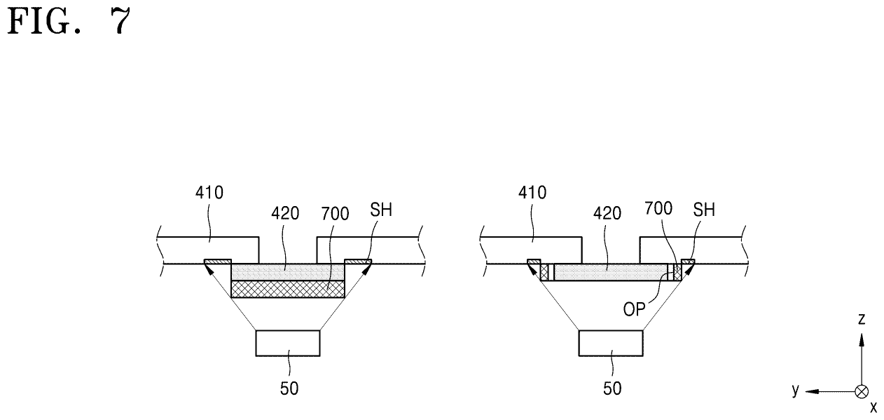

FIG. 7 is a schematic cross-sectional view illustrating a comparison between a mask assembly according to an embodiment and a mask assembly according to a comparative example. In detail, the mask assembly according to an embodiment is shown on the right, and the mask assembly according to a comparative example is shown on the left.

Referring to FIG. 7, the mask assembly MA according to an embodiment may prevent a shadow phenomenon. The shadow phenomenon refers to a phenomenon in which the deposition material is not deposited at a normal deposition thickness in case that it passes through the mask sheet 400 and is deposited on the display substrate DS. In case that the connection stick 420 is disposed above the support stick 700 as in the comparative example, a distance between the deposition source 50 and the support stick 700 may be reduced compared to the disclosure. Accordingly, a non-deposited area SH, in which the deposition material is unable to be deposited because the non-deposited area SH is obscured by the support stick 700, may increase. According to an embodiment, because the connection stick 420 is accommodated in the opening OP of the support stick 700, the distance between the deposition source 50 and the support stick 700 may increase compared to the comparative example. Accordingly, the non-deposited area SH, in which the deposition material is unable to be deposited because the non-deposited area SH is obscured by the support stick 700, may be decreased, and the shadow phenomenon may be prevented.

According to the comparative example, the cleaning solution used to clean the mask assembly MA may accumulate in the area where the connection stick 420 and the support stick 700 contact each other. Accordingly, it is difficult to discharge the cleaning solution, leading to a reduction in the lifespan of the mask assembly MA. According to an embodiment, because the connection stick 420 is accommodated in the opening OP of the support stick 700 and the cleaning solution is readily discharged through the opening OP, accumulation of the cleaning solution between the deposition source 420 and the support stick 700 may be prevented.

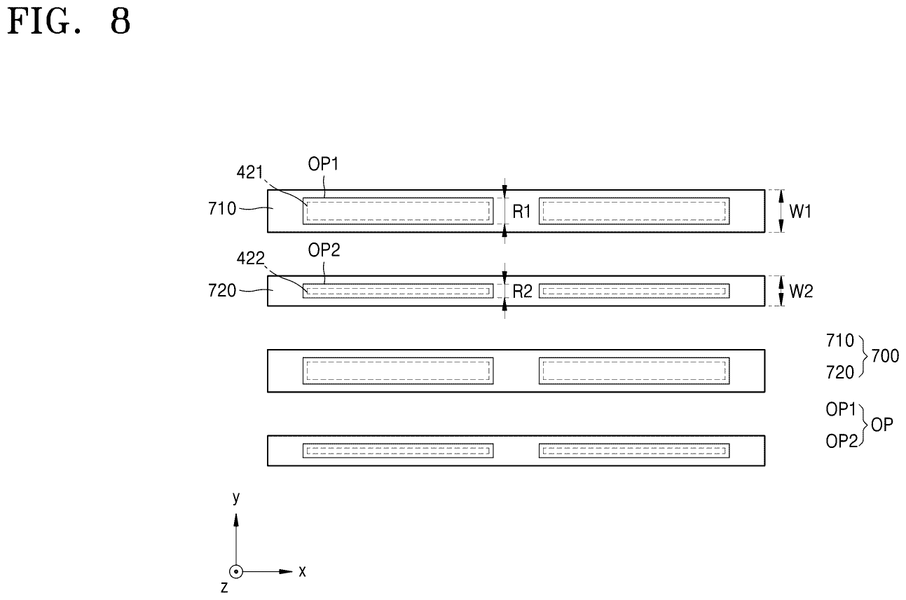

FIG. 8 is a schematic plan view of a support stick 700 according to an embodiment. Because the support stick 700 according to an embodiment is similar to the previously-described support stick 700, differences therebetween will now be focused on and described.

Referring to FIG. 8, according to an embodiment, a width W1 of a first support stick 710 may be different from a width W2 of a second support stick 720. For example, the width W1 of the first support stick 710 may be greater than the width W2 of the second support stick 720. According to an embodiment, a width R1 of an opening OP of the first support stick 710, for example, a first opening OP1, may be different from a width R2 of an opening OP of the second support stick 720, for example, a second opening OP2. For example, the width R1 of the first opening OP1 may be greater than the width R2 of the second opening OP2.

Because the width W1 of the first support stick 710 and the width W2 of the second support stick 720 are different from each other and the width R1 of the first opening OP1 and the width R2 of the second opening OP2 are different from each other, display apparatuses 1 of various sizes may be manufactured. For example, the first submask 411 and the second submask 412 may have different sizes, and the second submask 412 and the third submask 413 may have different sizes. Accordingly, a width of a first connection stick 421 connecting the first submask 411 to the second submask 412 may need to be different from that of a second connection stick 422 connecting the second submask 412 to the third submask 413. Accordingly, the first opening OP1 and the second opening OP2 accommodating the first connection stick 421 and the second connection stick 422 may need to have different widths. The width W1 of the first support stick 710 may need to be different from the width W2 of the second support stick 720.

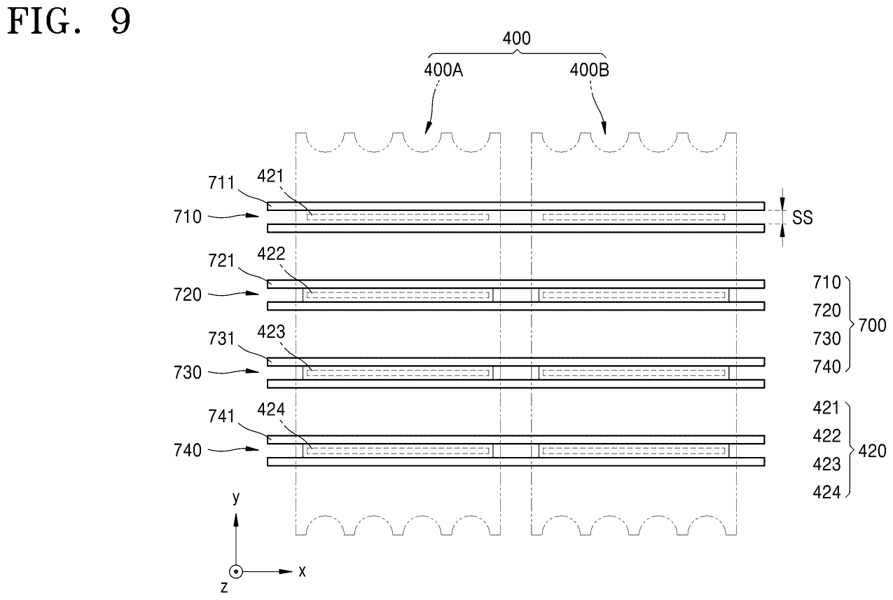

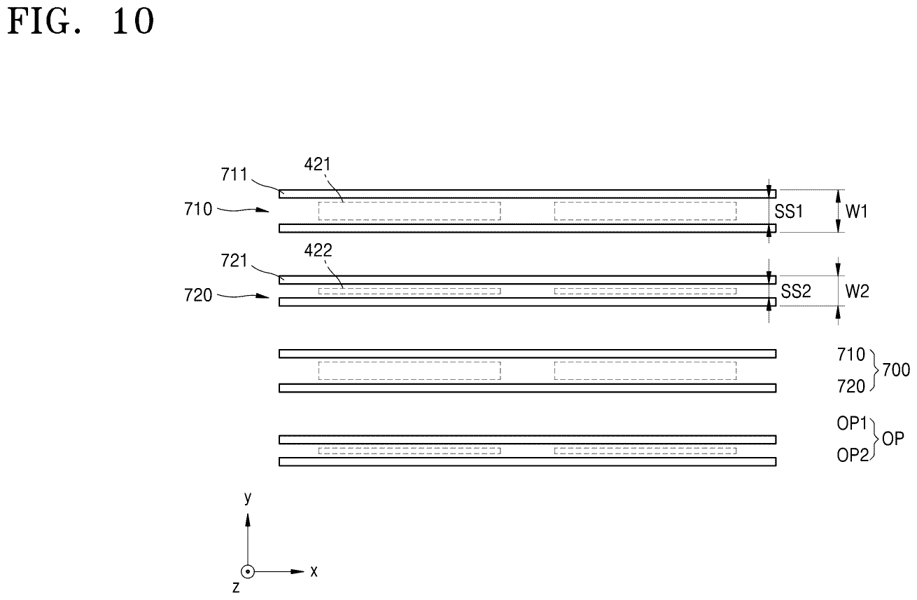

FIGS. 9 and 10 are schematic plan views of a support stick 700 according to other embodiments. Because the support stick 700 according to an embodiment is similar to the previously-described support stick 700, differences therebetween will now be focused on and described.

Referring to FIG. 9, according to an embodiment, the support stick 700 may include a pair of parallel substicks each extending in the first direction. For example, a first support stick 710 may include a pair of parallel first substicks 711 each extending in the first direction. The pair of parallel first substicks 711 may be spaced apart from each other in the second direction. A distance between the pair of parallel first substicks 711 may be defined as a separation distance SS.

A connection stick 420 may be accommodated between a pair of parallel substicks. According to an embodiment, a width of the separation distance SS may be formed to be greater than that of the connection stick 420 by at least about 12 μm but less than about 18 μm. Accordingly, the support stick 700 may secure a tolerance for accommodating the connection stick 420, and at the same time may enable a cleaning solution to be readily discharged without accumulating between the support stick 700 and the connection stick 420 during cleaning of the mask assembly MA.

Referring to FIG. 10, according to an embodiment, a first support stick 710 may include a pair of parallel first substicks 711 each extending in the first direction. The pair of parallel first substicks 711 may be spaced apart from each other by a separation distance SS1 in the second direction. A second support stick 720 may include a pair of parallel second substicks 721 each extending in the first direction. The pair of parallel second substicks 721 may be spaced apart from each other by a separation distance SS2 in the second direction.

In this case, according to an embodiment, a width W1 of the first support stick 710 may be different from a width W2 of the second support stick 720. For example, the width W1 of the first support stick 710 may be greater than the width W2 of the second support stick 720. According to an embodiment, the separation distance SS1 between first substicks 711 may be different from the separation distance SS2 between second substicks 721. For example, the separation distance SS1 between first substicks 711 may be greater than the separation distance SS2 between second substicks 721.

Because the width W1 of the first support stick 710 and the width W2 of the second support stick 720 are different from each other and the separation distance SS1 between first substicks 711 and the separation distance SS1 between second substicks 721 are different from each other, display apparatuses 1 of various sizes may be manufactured. For example, the first submask 411 and the second submask 412 may have different sizes, and the second submask 412 and the third submask 413 may have different sizes. Accordingly, a width of a first connection stick 421 connecting the first submask 411 to the second submask 412 may need to be different from that of a second connection stick 422 connecting the second submask 412 to the third submask 413. Accordingly, the separation distance SS1 between first substicks 711 accommodating the first connection stick 421 may need to be different from the separation distance SS2 between second substicks 721 accommodating the second connection stick 422. The width W1 of the first support stick 710 may need to be different from the width W2 of the second support stick 720.

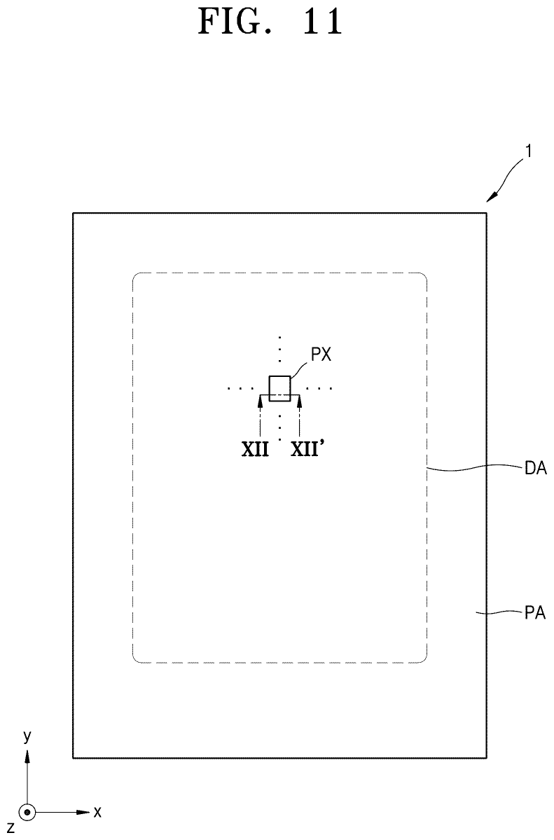

FIG. 11 is a schematic plan view of a display apparatus 1 manufactured using a display apparatus manufacturing apparatus, according to an embodiment.

Referring to FIG. 11, the display apparatus 1 manufactured according to an embodiment may include a display area DA and a peripheral area PA located around the display area DA. The display apparatus 1 may provide an image through an array of a plurality of pixels PX arranged in a two-dimensional (2D) manner in the display area DA.

The peripheral area PA provides no images, and may surround the entirety or a portion of the display area DA. A driver or the like for providing an electrical signal or power to a pixel circuit corresponding to each pixel PX may be disposed in the peripheral area PA. A pad that is an area where an electronic device or a printed circuit board (PCB) may be electrically connected may be disposed in the peripheral area PA.

A case where the display apparatus 1 may include an organic light-emitting diode OLED as a light-emitting element will now be described, but the display apparatus 1 according to the disclosure is not limited thereto. According to an embodiment, the display apparatus 1 may be a light-emitting display including an inorganic light-emitting diode, for example, an inorganic light-emitting display. The inorganic light-emitting diode may include a PN diode including materials based on an inorganic material semiconductor. In case that a voltage is applied to the PN junction diode in a forward direction, holes and electrons are injected, and energy generated by recombination of the holes and the electrons is converted into light energy to thereby emit light of a given color. The aforementioned inorganic light-emitting diode may have a width of several to several hundreds of micrometers. According to embodiments, the aforementioned inorganic light-emitting diode may be referred to as a micro LED. According to an embodiment, the display apparatus 1 may be a quantum dot light-emitting display.

The display apparatus 1 may be used as display screens of not only portable electronic apparatuses, such as mobile phones, smartphones, tablet personal computers (PCs), mobile communication terminals, electronic notebooks, electronic books, portable multimedia players (PMPs), navigation devices, and ultra mobile PCs (UMPCs) but also display screens of various products, such as televisions, notebooks, monitors, advertisement panels, and Internet of things (IoT) devices. The display apparatus 1 according to an embodiment may also be used in wearable devices, such as smart watches, watch phones, glasses-type displays, and head mounted displays (HMDs). The display apparatus 1 according to an embodiment may also be used as dashboards of automobiles, center information displays (CIDs) of the center fasciae or dashboards of automobiles, room mirror displays that replace the side mirrors of automobiles, and display screens arranged on the rear sides of front seats to serve as entertainment devices for back seat passengers of automobiles.

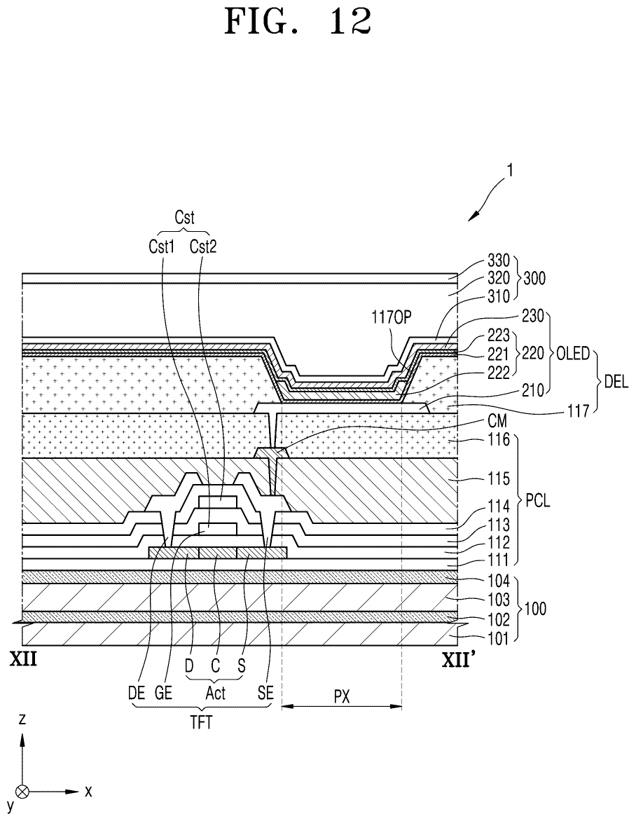

FIG. 12 is a schematic cross-sectional view of the display apparatus 1 manufactured using a display apparatus manufacturing apparatus, according to an embodiment, and may correspond to a cross-section of the display apparatus 1 taken along line XII-XII′ of FIG. 11.

Referring to FIG. 12, the display apparatus 1 may include a stack structure of the substrate 100, a pixel circuit layer PCL, a display element layer DEL, and an encapsulation layer 300. The above-described display substrate DS (see FIG. 1) may be, for example, a stack of at least one of the pixel circuit layer PCL, the display element layer DEL, and the encapsulation layer 300 on the substrate 100 during the manufacturing of the display apparatus 1.

The substrate 100 may have a multi-layered structure including a base layer including a polymer resin and an inorganic layer. For example, the substrate 100 may include the base layer including a polymer resin and an inorganic insulating layer. For example, the substrate 100 may include a first base layer 101, a first barrier layer 102, a second base layer 103, and a second barrier layer 104 which are sequentially stacked. The first and second base layers 101 and 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate (PC), cellulose triacetate (TAC), or/and cellulose acetate propionate (CAP). The first and second barrier layers 102 and 104 may include an inorganic insulating material, such as silicon oxide, silicon nitride, and/or silicon oxynitride. The substrate 100 may be flexible.

The pixel circuit layer PCL is disposed on the substrate 100. In FIG. 12, the pixel circuit layer PCL may include a thin-film transistor TFT, and a buffer layer 111, a first gate insulating layer 112, a second gate insulating layer 113, an interlayer insulating layer 114, a first planarization insulating layer 115, and a second planarization insulating layer 116 arranged below or/and above the components of the thin-film transistor TFT.

The buffer layer 111 may reduce or prevent infiltration of a foreign material, moisture, or ambient air from below the substrate 100 and may provide a flat surface to the substrate 100. The buffer layer 111 may include an inorganic insulating material, such as silicon oxide, silicon oxynitride, or silicon nitride, and may be a single layer or multiple layers including the inorganic insulating material.

The thin-film transistor TFT on the buffer layer 111 may include a semiconductor layer Act, and the semiconductor layer Act may include polysilicon. By way of example, the semiconductor layer Act may include, for example, amorphous silicon, an oxide semiconductor, or an organic semiconductor. The semiconductor layer Act may include a channel region C and a drain region D and a source region S respectively arranged on both sides of the channel region C. A gate electrode GE may overlap the channel region C.

The gate electrode GE may include a low resistance metal material. The gate electrode GE may include a conductive material including molybdenum (Mo), aluminum (Al), copper (Cu), and titanium (Ti), and may be formed as a multi-layer or single layer including the aforementioned materials.

The first gate insulating layer 112 between the semiconductor layer Act and the gate electrode GE may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The zinc oxide (ZnOₓ) may be a zinc oxide (ZnO) and/or a zinc peroxide (ZnO₂).

The second gate insulating layer 113 may be included to cover the gate electrode GE. Similar to the first gate insulating layer 112, the second gate insulating layer 113 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The zinc oxide (ZnOₓ) may be a zinc oxide (ZnO) and/or a zinc peroxide (ZnO₂).

An upper electrode Cst2 of a storage capacitor Cst may be disposed on the second gate insulating layer 113. The upper electrode Cst2 may overlap the gate electrode GE located therebelow. The gate electrode GE and the upper electrode Cst2, which overlap each other with the second gate insulating layer 113 therebetween, may constitute the storage capacitor Cst. In other words, the gate electrode GE may function as a lower electrode Cst1 of the storage capacitor Cst.

Thus, the storage capacitor Cst and the thin-film transistor TFT may overlap each other. According to an embodiment, the storage capacitor Cst and the thin-film transistor TFT may not overlap each other.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multi-layer including the aforementioned materials.

The interlayer insulating layer 114 may cover the upper electrode Cst2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnOₓ), or the like within the spirit and the scope of the disclosure. The zinc oxide (ZnOₓ) may be a zinc oxide (ZnO) and/or a zinc peroxide (ZnO₂). The interlayer insulating layer 114 may be a single layer or multi-layer including the aforementioned inorganic insulating materials.

A drain electrode DE and a source electrode SE may be located on the interlayer insulating layer 114. The drain electrode DE and the source electrode SE may be connected to the drain region D and the source region S through contact holes formed in the insulating layers below the drain electrode DE and the source electrode SE, respectively. The drain electrodes DE and the source electrode SE may include a highly conductive material. Each of the source electrode SE and the drain electrode DE may include a conductive material including Mo, Al, Cu, and Ti, and may be a multi-layer or single layer including the aforementioned materials. According to an embodiment, the drain electrodes DE and the source electrode SE may have a multi-layer structure of Ti/Al/Ti.

The first planarization insulating layer 115 may cover the drain electrode DE and the source electrode SE. The first planarization insulating layer 115 may include an organic insulating material, such as a commercial polymer (such as, polymethylmethacrylate (PMMA) or polystyrene (PS)), a polymer derivative having a phenol-based group, an acrylic polymer, an imide-based polymer, an acryl ether-based polymer, an amide-based polymer, a fluorine-based polymer, a p-xylene-based polymer, a vinyl alcohol-based polymer, or a blend thereof.

The second planarization insulating layer 116 may be located on the first planarization insulating layer 115. The second planarization insulating layer 116 may include the same material as the first planarization insulating layer 115, and may include an organic insulating material, such as a commercial polymer (such as, polymethylmethacrylate (PMMA) or polystyrene (PS)), a polymer derivative having a phenol-based group, an acrylic polymer, an imide-based polymer, an acryl ether-based polymer, an amide-based polymer, a fluorine-based polymer, a p-xylene-based polymer, a vinyl alcohol-based polymer, or a blend thereof.

The display element layer DEL may be disposed on the pixel circuit layer PCL having the above-described structure. The display element layer DEL may include the organic light-emitting diode OLED as a display element (for example, a light-emitting element), and the organic light-emitting diode OLED may include a stack structure of a pixel electrode 210, an intermediate layer 220, and a common electrode 230. For example, the organic light-emitting diode OLED may emit red light, green light, or blue light, or may emit red light, green light, blue light, or white light. The organic light-emitting diode OLED may emit light through a light-emitting area, and the light-emitting area may be defined as a pixel PX.

The pixel electrode 210 of the organic light-emitting diode OLED may be electrically connected to the thin-film transistor TFT through contact holes formed in the second planarization insulating layer 116 and the first planarization insulating layer 115 and a contact metal CM disposed on the first planarization insulating layer 115.

The pixel electrode 210 may include conductive oxide such as indium tin oxide (ITO), indium zinc oxide (IZO), zinc oxide (ZnO), indium oxide (In₂O₃), indium gallium oxide (IGO), or aluminum zinc oxide (AZO). According to an embodiment, the pixel electrode 210 may include a reflection layer including, for example, silver (Ag), magnesium (Mg), aluminum (Al), platinum (Pt), palladium (Pd), gold (Au), nickel (Ni), neodymium (Nd), iridium (Ir), chromium (Cr), or a compound of these materials. According to an embodiment, the pixel electrode 210 may further include a film formed of ITO, IZO, ZnO, or In₂O₃ above/below the aforementioned reflection layer.

A pixel defining layer 117 having an opening 117OP through which a center portion of the pixel electrode 210 is exposed is disposed on the pixel electrode 210. The pixel defining layer 117 may include an organic insulating material and/or an inorganic insulating material. The opening 117OP may define a light-emission area of light emitted by the organic light-emitting diode OLED. For example, a width of the opening 117OP may correspond to a size/width of the light-emission area. Accordingly, a size and/or width of a pixel PX may depend on the size and/or width of an opening 117OP of the pixel defining layer 117 corresponding to the pixel PX.

The intermediate layer 220 may include an emission layer 222 formed to correspond to the pixel electrode 210. The emission layer 222 may include a low molecular or high molecular organic material that emits light of a selectable color. By way of example, the emission layer 222 may include an inorganic insulating material or may include quantum dots.

According to an embodiment, the intermediate layer 220 may include a first functional layer 221 and a second functional layer 223 respectively arranged below and above the emission layer 222. The first functional layer 221 may include, for example, a hole transport layer (HTL), or may include an HTL and a hole injection layer (HIL). The second functional layer 223, which is a component disposed above the emission layer, may include an electron transport layer (ETL) and/or an electron injection layer (EIL). The first functional layer 221 and/or the second functional layer 223 may be a common layer that entirely covers the substrate 100, similar to the common electrode 230 to be described later.

The common electrode 230 may be disposed on the pixel electrode 210, and may overlap the pixel electrode 210. The common electrode 230 may include a conductive material having a low work function. For example, the common electrode 230 may include a (semi)transparent layer including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy of these materials. By way of example, the common electrode 230 may further include a layer, such as ITO, IZO, ZnO, or In₂O₃, on the (semi)transparent layer including any of the above-described materials. The common electrode 230 may be integrally formed to entirely cover the substrate 100.

The encapsulation layer 300 may be disposed on the display element layer 300 and cover the display element layer DEL. The encapsulation layer 300 may include at least one inorganic encapsulation layer and at least one organic encapsulation layer. According to an embodiment, FIG. 12 illustrates that the encapsulation layer 300 may include a first inorganic encapsulation layer 310, an organic encapsulation layer 320, and a second inorganic encapsulation layer 330.

The first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include an acrylic resin, an epoxy-based resin, polyimide, and polyethylene. According to an embodiment, the organic encapsulation layer 320 may include acrylate. The organic encapsulation layer 320 may be formed by curing a monomer or by coating a polymer. The organic encapsulation layer 320 may be transparent.

Although not shown in the drawings, a touch sensor layer may be disposed on the encapsulation layer 300, and an optical functional layer may be disposed on the touch sensor layer. The touch sensor layer may obtain coordinate information based on an external input, for example, a touch event. The optical functional layer may reduce reflectance of light (external light) externally incident toward the display apparatus 1, and/or may improve color purity of light emitted by the display apparatus 1. According to an embodiment, the optical functional layer may include a phase retarder and/or a polarizer. The phase retarder may be of a film type or liquid coating type, and may include a λ/2 phase retarder and/or a λ/4 phase retarder. The polarizer may also be of a film type or liquid coating type. The film type polarizer may include a stretchable synthetic resin film, and the liquid coating type polarizer may include liquid crystals arranged in a selectable arrangement. The phase retarder and the polarizer may further include protective films, respectively.

An adhesive member may be disposed between the touch electrode layer and the optical functional layer. The adhesive member may employ a general one in the art without limitation. The adhesive member may be a pressure sensitive adhesive (PSA).

According to embodiments, the deposition quality of a deposition material may be improved by improving the alignment of a mask assembly.

Effects of the disclosure are not limited to the aforementioned effects, and other effects not mentioned will be clearly understood by those skilled in the art from the description of the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope and as defined by the following claims.

What is claimed is:

1. A mask assembly comprising:
a mask frame comprising an opening area;
at least one mask sheet covering the opening area of the mask frame; and
a support stick disposed between the mask frame and the at least one mask sheet, the support stick extending in a first direction to traverse the opening area, the support stick having ends fixed to the mask frame, wherein
the at least one mask sheet comprises:
a plurality of submasks disposed side by side in a direction intersecting the first direction in which the support stick extends; and
a connection stick disposed between the plurality of submasks and connecting two adjacent submasks among the plurality of submasks, and
the connection stick overlaps the support stick in a plan view.

2. The mask assembly of claim 1, wherein
the support stick comprises an opening formed in the first direction, and
the connection stick is accommodated in the opening.

3. The mask assembly of claim 2, wherein a width of the opening is formed to be larger than a width of the connection stick by at least about 12 μm but less than about 18 μm.

4. The mask assembly of claim 2, wherein a thickness of the connection stick and a thickness of the support stick are same.

5. The mask assembly of claim 4, wherein the plurality of submasks contact the support stick.

6. The mask assembly of claim 1, wherein
the plurality of submasks comprise a first submask, a second submask, and a third submask, disposed side by side in a second direction, and
the support stick comprises:
a first support stick extending in the first direction between the first submask and the second submask, in a plan view, the first support stick including a first opening accommodating a first connection stick between the first submask and the second submask; and
a second support stick extending in the first direction between the second submask and the third submask, in a plan view, the second support stick including a second opening accommodating a second connection stick disposed between the second submask and the third submask.

7. The mask assembly of claim 6, wherein a width of the first support stick and a width of the second support stick are different.

8. The mask assembly of claim 7, wherein a width of the first opening and a width of the second opening are different.

9. The mask assembly of claim 1, wherein
the at least one mask sheet comprises a first mask sheet and a second mask sheet disposed side by side in the first direction,
the support stick comprises a first opening and a second opening spaced apart from each other in the first direction, and
a connection stick of the first mask sheet is accommodated in the first opening, and a connection stick of the second mask sheet is accommodated in the second opening.

10. The mask assembly of claim 1, wherein
the support stick comprises a pair of parallel substicks each extending in the first direction, and
the connection stick is accommodated between the pair of parallel substicks.

11. The mask assembly of claim 10, wherein a distance between the pair of parallel substicks is formed to be larger than a width of the connection stick by at least about 12 μm but less than about 18 μm.

12. The mask assembly of claim 10, wherein
the plurality of submasks comprise a first submask, a second submask, and a third submask, disposed side by side in a second direction, and
the support stick comprises:
a first support stick extending in the first direction between the first submask and the second submask, in a plan view, the first support stick including a pair of parallel first substicks to accommodate a first connection stick between the first submask and the second submask; and
a second support stick extending in the first direction between the second submask and the third submask, in a plan view, the second support stick including a pair of parallel second substicks to accommodate a second connection stick between the second submask and the third submask.

13. The mask assembly of claim 12, wherein a separation distance between the pair of parallel first substicks is different from a separation distance between the pair of parallel second substicks.

14. An apparatus for manufacturing a display apparatus, the apparatus comprising:
a mask assembly facing a display substrate; and
a deposition source facing the mask assembly on a side opposite to a side on which the display substrate is located, wherein
the mask assembly comprises:
a mask frame comprising an opening area;
at least one mask sheet covering the opening area of the mask frame; and
a support stick disposed between the mask frame and the at least one mask sheet, the support stick extending in a first direction to traverse the opening area, the support stick having ends fixed to the mask frame,
the at least one mask sheet comprises:
a plurality of submasks disposed side by side in a direction intersecting the first direction in which the support stick extends; and
a connection stick disposed between the plurality of submasks and connecting two adjacent submasks among the plurality of submasks, and
the connection stick overlaps the support stick in a plan view.

15. The apparatus of claim 14, wherein
the support stick comprises an opening formed in the first direction, and
the connection stick is accommodated in the opening of the support stick.

16. The apparatus of claim 15, wherein a width of the opening is formed to be larger than a width of the connection stick by at least about 12 μm but less than about 18 μm.

17. The apparatus of claim 14, wherein
the plurality of submasks comprise a first submask, a second submask, and a third submask, disposed side by side in a second direction, and
the support stick comprises:
a first support stick extending in the first direction between the first submask and the second submask, in a plan view, the first support stick including a first opening accommodating a first connection stick between the first submask and the second submask; and
a second support stick extending in the first direction between the second submask and the third submask, in a plan view, the second support stick including a second opening accommodating a second connection stick between the second submask and the third submask.

18. The apparatus of claim 17, wherein a width of the first support stick and a width of the second support stick are different.

19. The apparatus of claim 18, wherein a width of the first opening and a width of the second opening are different.

20. The apparatus of claim 14, wherein
the support stick comprises a pair of parallel substicks each extending in the first direction, and
the connection stick is accommodated between the pair of parallel substicks.
